(19) United States
(12) Patent Application Publication
(10) Pub. No.: US 2026/0142545 A1
(43) Pub. Date: May 21, 2026

(54) ELECTROMAGNETIC ACTUATOR, EXPOSURE APPARATUS, AND METHOD OF MANUFACTURING PRODUCT

(71) Applicant: CANON KABUSHIKI KAISHA, Tokyo (JP)

(72) Inventors: RIKUTO FUJII, Hyogo (JP); NORIHIRO SAKURAKAWA, Tochigi (JP)

(21) Appl. No.: 19/377,345

(22) Filed: Nov. 3, 2025

(30) Foreign Application Priority Data
Nov. 15, 2024 (JP) 2024-199435

(51) Int. Cl. H02K 41/02; G03F 7/00; H02K 1/20

(52) U.S. Cl. CPC H02K 41/02; G03F 7/70358; H02K 1/20

(57) ABSTRACT

An electromagnetic actuator includes a stator extending in a first direction, and an element configured to be movable along the first direction, wherein one of the stator and the element includes a magnet and the other of the stator and the element includes a coil. The element has a through-hole extending in the first direction, the stator extends through the through-hole, and the element has, at a position along the through-hole, a hole configured for fluid to flow through.

### BACKGROUND

### Field of the Technology

The present disclosure relates to an electromagnetic actuator, an exposure apparatus, and a method of manufacturing a product.

### Description of the Related Art

An actuator including a stator and a movable element is sometimes used as a unit for moving an object. Japanese Patent Laid-Open No. 2003-116260 discusses an electromagnetic actuator, in which magnets are arranged in either a stator or a movable element, and coils are arranged in the other of the stator and the movable element. The actuator applies current to the coils to generate thrust force in the movable element.

When an electric current is supplied to the coils, the coils generate heat. If this heat is transmitted to the magnet and the magnet reaches a high temperature, the magnet may undergo demagnetization. Once the magnet is demagnetized, the actuator can no longer generate the desired thrust.

Japanese Patent Laid-Open No. 2003-116260 discusses a hole serving as a flow path forming unit for a coolant being formed inside a mass element surrounding the stator and the movable element; however, consideration is not given to a flow path forming unit for the movable element.

### SUMMARY

The present disclosure is directed to provision of an electromagnetic actuator capable of reducing demagnetization of a magnet by using a flow path in the movable element.

An aspect of the present disclosure provides an electromagnetic actuator that includes a stator extending in a first direction, and an element configured to be movable along the first direction, wherein one of the stator and the element includes a magnet and the other of the stator and the element includes a coil. The element has a through-hole extending in the first direction, the stator extends through the through-hole, and the element has, at a position along the through-hole, a hole configured for fluid to flow through.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram illustrating a configuration of a substrate processing apparatus.

FIG. 2 is a schematic diagram illustrating a reticle stage.

FIG. 3 is a schematic diagram illustrating an example of an arrangement of a first flow path.

FIGS. 4A to 4C are diagrams each illustrating an example of an electromagnetic actuator.

FIG. 5 is a diagram illustrating another example of the electromagnetic actuator.

FIGS. 6A and 6B are diagrams illustrating another example of the electromagnetic actuator.

FIG. 7 is a diagram illustrating another example of the electromagnetic actuator.

FIGS. 8A and 8B are diagrams illustrating another example of the electromagnetic actuator.

FIG. 9 is a diagram illustrating another example of the electromagnetic actuator.

FIG. 10 illustrates an example of an arrangement of a third flow path according to a second embodiment.

FIG. 11 illustrates an example in which the first flow path and the third flow path are connected to each other via a movable tube.

FIG. 12 is a flowchart of a method of manufacturing a product.

### DESCRIPTION OF THE EMBODIMENTS

Embodiments of the present disclosure will be described below with reference to the accompanying drawings. The following embodiments are not intended to limit the claimed disclosure. While a plurality of features is described in the embodiments, not all of the plurality of features is necessarily essential to the present disclosure, and the embodiments may be freely combined. In the drawings, identical or similar constituent elements are denoted by identical reference numerals, and redundant descriptions thereof are omitted.

In the present specification and the drawings, directions are described with reference to an X-Y-Z coordinate system in which a vertical direction is a Z-axis direction, a horizontal plane perpendicular to the vertical direction is an X-Y plane, and axes are orthogonal to one another. However, in a case where the X-Y-Z coordinate system is not described in a drawing, the coordinate system in the drawing is given priority.

A specific configuration of each embodiment will be described below.

### <First Embodiment>

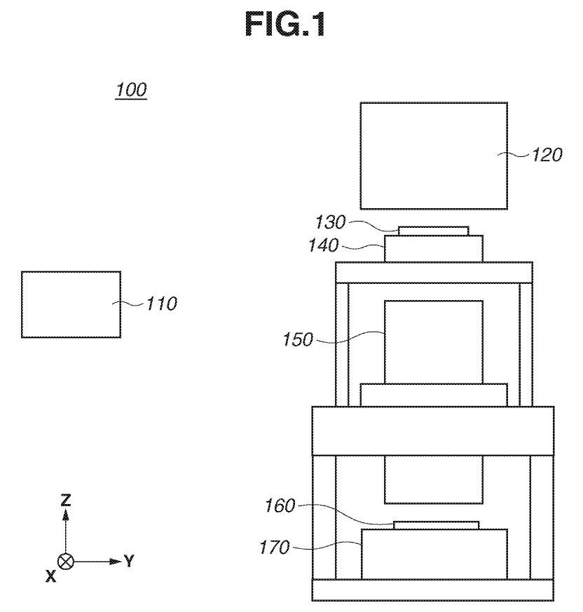

FIG. 1 is a schematic diagram illustrating a configuration of a substrate processing apparatus 100 according to a first embodiment. In the present embodiment, the substrate processing apparatus 100 is an exposure apparatus within which a substrate is exposed to light via a projection optical system to form a pattern of an original plate (mask or reticle) using a step-and-repeat method or a step-and-scan method.

The substrate processing apparatus 100 includes an illumination optical system 120 that emits light, a projection optical system 150, a reticle stage 140 capable of driving a reticle 130 while holding the reticle 130, a substrate stage 170 capable of driving a substrate 160 while holding the substrate 160, and a control unit 110. The reticle 130 is, for example, a master plate on which a pattern (e.g., circuit pattern) to be transferred is formed of chromium on the surface of quartz glass. The substrate 160 is made of, for example, single-crystal silicon. In a case where the substrate processing apparatus 100 is an exposure apparatus, the surface of the substrate 160 to be conveyed to the substrate processing apparatus 100 is coated with a photosensitive material (resist). The control unit 110 controls each component of the substrate processing apparatus 100. Here, the illumination optical system 120 is a pattern forming unit that forms a pattern on the substrate 160. In the present embodiment, an example of a lithography apparatus that forms a pattern with use of light is described, and the pattern forming unit is the illumination optical system 120. Alternatively, a lithography apparatus that thermally cures a thermosetting material onto which the pattern has been transferred may be employed. The pattern forming unit in this case is, for example, a heating unit that heats the thermosetting material.

The control unit 110 includes a processing unit, a bus, a read-only memory (ROM), a random-access memory (RAM), and a storage device. Each constituent element functions according to programs. The processing unit is a processing device that performs computation for control according to programs and controls each constituent element connected to the bus. The processing unit may include a central processing unit (CPU), a programmable logic device (PLD) such as a field-programmable gate array (FPGA) circuit, an application-specific integrated circuit (ASIC), a computer with built-in programs, or any combination thereof. The ROM is a data read-only memory in which programs and data are stored. The RAM is a data read/write memory, and is used for storing programs and data. The RAM is used for temporarily storing data such as results of computations performed by the CPU. The storage device is also used for storing programs and data. The storage device is also used as an area for temporarily storing data and programs for an operating system (OS) of the control unit 110. Although data input/output speed is slower than that of RAM, the storage device can store large volumes of data. The storage device may be a non-volatile storage device capable of storing data as persistent data so that the stored data can be referred to for a long period of time. The storage device is mainly composed of a magnetic storage device (hard disk drive (HDD)), and may also read and write data when external media such as a compact disk (CD), a digital versatile disk (DVD), or a memory card, are loaded.

The control unit 110 may be configured integrally with the other components of the substrate processing apparatus 100 (i.e., within a common housing), or may be configured as a separate component from the other components of the substrate processing apparatus 100 (in another housing).

In the substrate processing apparatus 100, exposure light from a light source illuminates the reticle 130 held on the reticle stage 140 via the illumination optical system 120. The light that has passed through the reticle 130 is projected onto the substrate 160 via the projection optical system 150. At this time, light from the pattern formed on the reticle 130 is formed as an image on the surface of the substrate 160, and a shot area on the substrate 160 (photosensitive material) is exposed to light with the pattern image. The substrate processing apparatus 100 exposes the shot area on the substrate 160 to light in this manner, and a plurality of shot areas may be exposed to light in a similar manner.

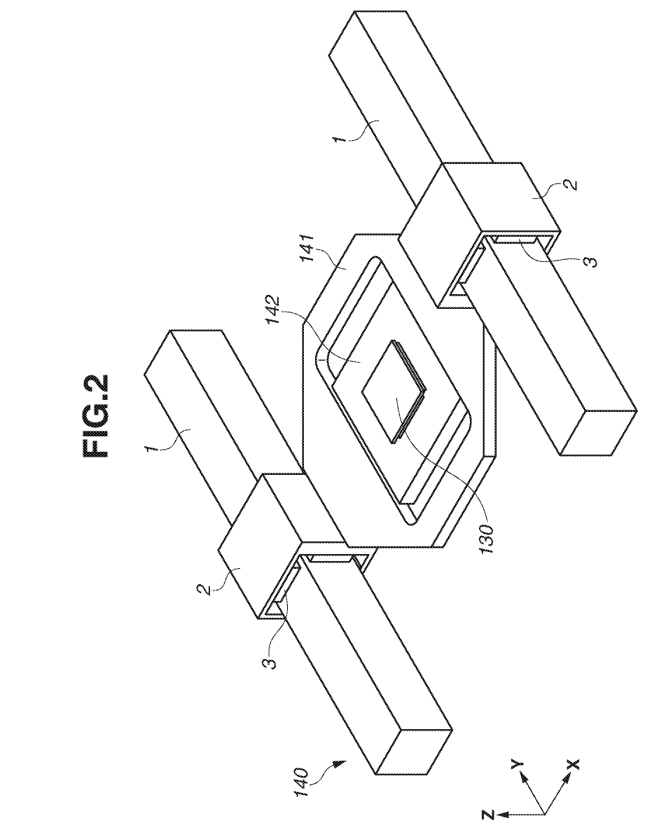

FIG. 2 is a schematic diagram illustrating the reticle stage 140. The reticle stage 140 includes two electromagnetic actuators (linear motors), each including a stator 1 extending in the Y-axis direction (first direction), and a movable element 2 movable along the Y-axis direction.

Each movable element 2 has a through-hole extending through the movable element 2 in the Y-axis direction. This through-hole is formed as an opening extending through an interior of the movable element 2 in the Y-axis direction, and extends through the movable element 2. The through-hole is configured for the stator 1 to extend therethrough. At least a portion of the stator 1 is arranged within the opening of the movable element 2, and, in the present embodiment, is positioned in the through-hole provided in the movable element 2. The opening of the movable element 2 may extend in the Y-axis direction without necessarily extending through an entire length of the movable element 2, as long as the movable element 2 is capable of moving an amount in the Y-axis direction relative to the stator 1. In the present embodiment, a description is provided of an example in which a coil is disposed in the stator 1, and a magnet 3 is disposed in the movable element 2.

Applying current to the coil generates thrust (driving force) in the magnet 3, which moves the movable element 2.

The reticle stage 140 includes a coupling portion (coupling member) 141 positioned between a movable element 2 that is provided on a +X direction side of the coupling portion 141 and another movable element 2 that is provided on a -X direction side of the coupling portion 141. In other words, the reticle stage 140 according to the present embodiment includes a stator 1 and movable element 2 on each side of a coupling portion 141. The coupling portion 141 is configured to support a detachably mounted reticle chuck 142, which holds the reticle 130. During exposure in the substrate processing apparatus 100, the movable elements 2 move along the Y-axis direction, thereby moving the reticle 130 to a target position. That is, during exposure, the coupling portion 141, the reticle chuck 142, and the reticle 130 are driven objects. When the reticle 130 is not mounted on the reticle chuck 142, the coupling portion 141 and the reticle chuck 142 are driven objects.

In a case where an actuator is driven at high speed, a large current is applied to the coil to increase the thrust for moving the movable element 2. At this time, the coil and the magnet 3 may be positioned as close to each other as possible, to efficiently generate thrust. Here, applying large current to the coil generates heat. If heat from the coil is transferred to the magnet 3 that is arranged in proximity to the coil, the temperature of the magnet 3 rises. In a case where the magnet 3 is a rare-earth magnet, such as a neodymium magnet, demagnetization occurs at high temperature, resulting in a reduction in the generated thrust. If the temperature of the magnet 3 further rises, irreversible demagnetization occurs, in which the magnetic force of the magnet 3 does not recover even after the temperature decreases. In a case where such irreversible demagnetization occurs, the actuator can no longer perform a desired operation (e.g., generation of desired thrust).

To address the demagnetization, in the movable element 2 according to the present embodiment, a fluid serving as a coolant is caused to flow at a position along the through-hole that is provided in the movable element 2, thus reducing the temperature rise of the magnet 3 and reducing the occurrence of demagnetization of the magnet 3.

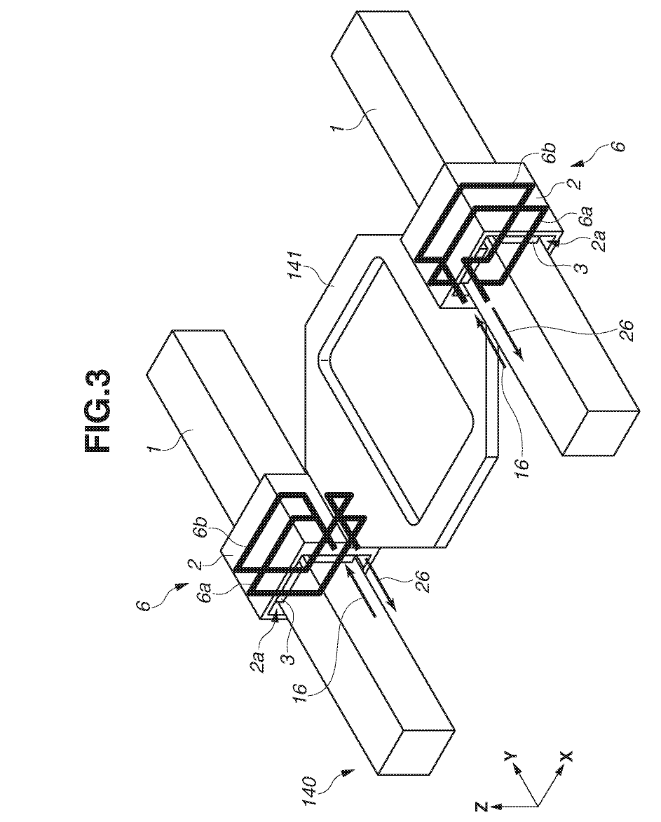

FIG. 3 is a schematic diagram illustrating an example of an arrangement of first flow paths 6 in the present embodiment. In the example in FIG. 3, the fluid flows through each movable element 2 at a plurality of mutually different positions in the Y-axis direction (the first direction). That is, each movable element 2 includes a second hole 6a through which the fluid flows along the through-hole 2a (a first hole) at a first position in the Y-axis direction, and a third hole 6b through which the fluid flows along the through-hole at a second position in the Y-axis direction. The second position is different from the first position. Each of the second hole 6a and the third hole 6b are part of a flow path, i.e. passage, that extends around the through-hole 2a in a circumferential direction of the through-hole 2a.

One flow path of the first flow paths 6 is arranged to extend around an axis parallel to the Y-axis so as to surround the through-hole 2a in the movable element 2, and the fluid flows through respective first flow paths 6 around respective through-holes, and is thereafter discharged from the respective first flow paths 6. Causing the fluid to flow at a plurality of positions in the Y-axis direction, as in the example in FIG. 3, can further reduce the heating of the magnet 3.

As indicated by arrow 16 in FIG. 3, the fluid is supplied from the -Y-direction side. The flow path branches so that the fluid flows into the first flow path 6 located at different positions in the Y-axis direction. In each of the branched flow paths, the fluid flows around the through-hole and along the through-hole 2a in the movable element 2. As shown in FIG. 3, the plurality of branched flow paths merge, and the fluid is discharged on the -Y-direction side, as indicated by arrow 26. Positions through which the fluid flows need not necessarily be the plurality of different positions in the Y-axis direction, and a single position in the Y-axis direction is also applicable. In the example in FIG. 3, the fluid flows along two different positions in the Y-axis direction, but may flow along three or more positions in the Y-axis direction.

In the present embodiment, the description has been provided of an example in which the respective first flow paths 6 cause the fluid to flow so as to surround the through-hole 2a in the corresponding movable elements 2 in a cross section orthogonal to the Y-axis direction (X-Z cross section). Alternatively, to cause the fluid to flow in an cross section inclined with respect to the X-Z cross section, the first flow paths 6 may be arranged so as to surround the through-hole 2a in the corresponding movable element 2 around the axis that is parallel to the Y-axis in a cross-sectional view of the inclined cross section.

The first flow path 6 is, for example, provided by arrangement (insertion) of a flow path forming member (unit) such as a polyurethane tube or a metal pipe on the surface (outer surface) of the movable element 2. The tube or the metal pipe has, for example, a circular shape in the X-Z cross section, and is disposed at a position along the through-hole 2a. Alternatively, the first flow path 6 is provided by cutting the movable element 2 (portion corresponding to the wall thickness of the movable element 2) with a tool such as a drill. The hole (the first flow path 6) formed by such cutting serves as piping for allowing the fluid to flow, and serves as a flow path. In a case where the hole is formed using a drill or the like, the hole is formed from the outside of the movable element 2 to form the flow path. To prevent the fluid from leaking from the first flow path 6 formed in the movable element 2, a member serving as a lid is disposed at a position at which the hole formed in the movable element 2 communicates with an external space.

Alternatively, in a case where the movable element 2 is formed using a three-dimensional (3D) printer or the like, the movable element 2 is formed based on a design in which the first flow path 6 through which the fluid flows is provided, so that the first flow path 6 that functions as piping for allowing the fluid to flow is provided. In a case where the first flow path 6 is provided on the surface (outer surface) of the movable element 2, a cooling unit provided with the first flow path 6 through which the fluid flows may be made attachable to and detachable from the movable element 2 so that the cooling unit can be removed from the movable element 2 for maintenance. As described above, the first flow path 6 may be formed as a hole through which the fluid flows, or as a pipe or similar component having a hollow through which the fluid flows, and includes a flow path along the circumferential direction of the through-hole, which is an opening provided in each movable element 2 (here, a flow path extending around an axis in the Y-axis direction).

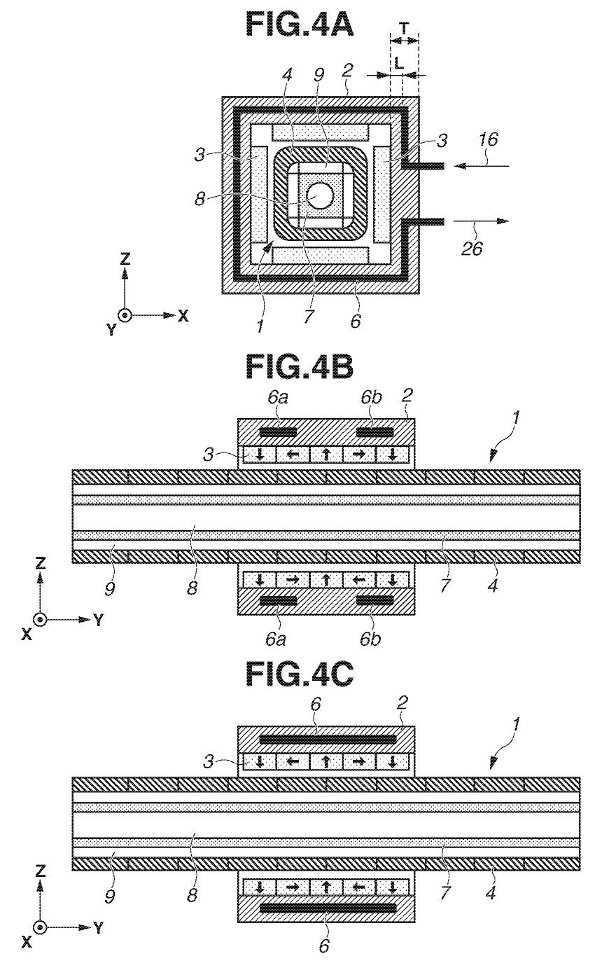

FIGS. 4A to 4C are diagrams each illustrating an example of the electromagnetic actuator according to the present embodiment. FIG. 4A is a cross-sectional view illustrating the X-Z cross section of the electromagnetic actuator. The stator 1 includes coils 4, yokes 9 that are bonded to the corresponding coils 4, a support member 7 that supports the yokes 9, and a second flow path 8 through which a fluid (coolant) for cooling the stator 1 flows. The stator is arranged inside the support member 7. For example, a plurality of coils 4 and a plurality of yokes 9 are provided. Each yoke 9 is, for example, a plate-like member containing iron, and serves to increase the density of magnetic flux generated when a current flows through the coil 4, thus enhancing the magnetic field. To enhance the effect of cooling the stator 1 with the fluid flowing through the second flow path 8, the support member 7 may be a material having high thermal conductivity such as aluminum, copper, silver, or a high thermal conductivity ceramic. The movable element 2 includes a plurality of magnets 3. In the example in FIG. 4A, the movable element 2 includes two pairs of magnets 3. The paired magnets 3 face each other with the stator 1 interposed therebetween. One of the two pairs of magnets 3 is a pair of magnets facing each other in the vertical direction, and the other one is a pair of magnets facing each other in the horizontal direction.

The second flow path 8 is, for example, provided by press-fitting of a tube, a metal pipe, or the like into a hole inside the support member 7. Alternatively, the second flow path 8 is provided by forming a hole in the support member 7 by cutting the support member 7 with a tool such as a drill.

Examples of the fluid flowing through the first flow path 6 and the second flow path 8 include insulating oil, pure water, and antifreeze. These fluids may be subjected to temperature adjustment when being supplied. The temperature adjustment is performed by the control unit 110 controlling a temperature adjustment unit, e.g., a heater. The control is performed based on, for example, a result of measuring the temperature of the magnet 3 itself or the temperature of a member near the magnet 3 (e.g., the movable element 2), or a result of measuring the temperature of the fluid discharged from the first flow path 6 and the second flow path 8. To perform the temperature measurement, for example, a sensor is provided on a member to be measured or each flow path.

At least one of the flow rate (flow velocity) and temperature of the fluid flowing through the first flow path 6 may be adjusted depending on a moving state of the movable element 2. To perform this adjustment, for example, the control unit 110 controls a supply unit that supplies the fluid or an adjustment mechanism provided in a pipe or tube through which the fluid flows. The flow rate is adjusted by, for example, control of an electromagnetic valve. The temperature adjustment is performed by, for example, control of the temperature adjustment unit (the heater or the like), by the control unit 110. For example, in a case where the movable element 2 is moving at high speed or has been moving for a long period of time with short downtime, the control unit 110 performs at least one of increasing of the flow rate (flow velocity) of the fluid flowing through the first flow path 6 and lowering of the temperature of the fluid.

FIG. 4B is a cross-sectional view illustrating the Y-Z cross section of the electromagnetic actuator. The plurality of coils 4 are arrayed in the Y-axis direction. The support member 7, the second flow path 8, and the yoke 9 extend in the Y-axis direction. The array of the plurality of magnets 3 in the movable element 2 is, for example, a Halbach array in which a magnet magnetized in the Y-axis direction and a magnet magnetized in the Z-axis direction are alternately arranged. The flow path for the coolant in the movable element 2 may be a single first flow path 6 having a large width in the Y-axis direction, as illustrated in FIG. 4C, instead of arranging each of a plurality of first flow paths 6 at different positions in the Y-axis direction. The cross-sectional shape of the hole forming the first flow path 6 is not limited to a rectangle, as illustrated in FIGS. 4B and 4C, but may be a perfect circle, an ellipse, or other shapes. The cross-sectional shape of the hole forming other flow paths, such as the second flow path 8, may also vary.

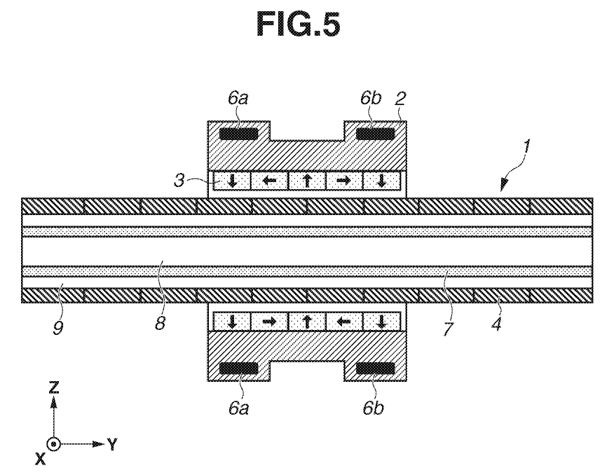

FIG. 5 is a diagram illustrating another example of the electromagnetic actuator according to the present embodiment. FIG. 5 illustrates an example in which convex portions (rib-shaped) are provided on the surface of the movable element 2 along the circumferential direction of the through-hole around the axis parallel to the Y-axis, the first flow path 6 formed by a hole is disposed in the respective convex portions, and a flow path formed by a hole is formed along the circumferential direction of the through-hole around an axis parallel to the Y-axis. Providing such convex portions in the movable element 2 can increase the rigidity of the movable element 2, compared with a case where such convex portions are not provided, and the possibility of damage to the movable element 2 when the movable element 2 moves at high speed is reduced.

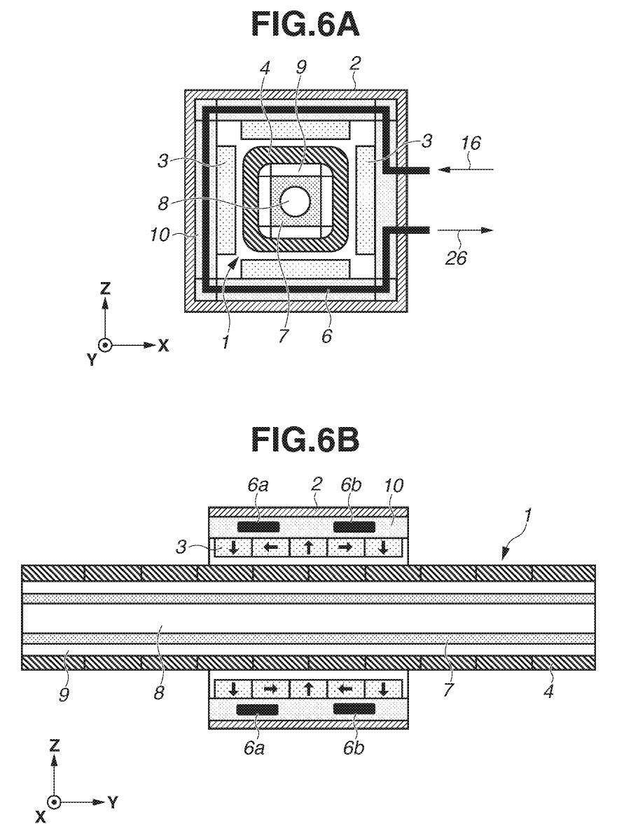

FIGS. 6A and 6B are diagrams each illustrating another example of the electromagnetic actuator according to the present embodiment. FIG. 6A is a cross-sectional view illustrating the X-Z cross section of the electromagnetic actuator. In the example in FIGS. 6A and 6B, in the movable element 2, the magnets 3 are supported by a back yoke 10, a hole extending through the back yoke 10 functions as the first flow path 6, and the fluid serving as the coolant flows through the hole. A member (pipe, such as a tube) embedded inside the back yoke 10 may function as the first flow path 6. The back yoke 10 contains a magnetic material, and increases the magnetic flux of the magnets 3 linked with the coil 4.

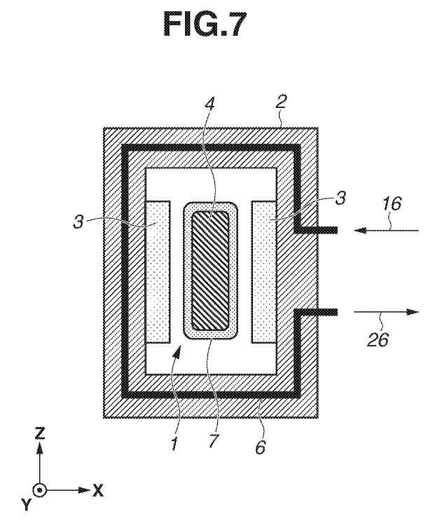

FIG. 7 is a diagram illustrating another example of the electromagnetic actuator according to the present embodiment and is a cross-sectional view illustrating the X-Z cross section of the electromagnetic actuator. In the electromagnetic actuator illustrated in FIG. 7, the movable element 2 includes a pair of magnets 3 facing each other in a right-and-left direction with the stator 1 interposed therebetween in the X-axis direction, but does not include a pair of magnets 3 facing each other in an up-and-down direction. In this manner, the number of pairs of magnets 3 used in the electromagnetic actuator is not limited to two pairs, as in the electromagnetic actuator as illustrated in FIGS. 6A and 6B, where the pair of magnets 3 in the up-and-down direction and the pair of magnets 3 in the right-and-left direction are disposed. According to the configuration in FIG. 7, the electromagnetic actuator can be miniaturized. In a case where the pair of magnets 3 in the up-and-down direction is not provided as illustrated in FIG. 7, an opening (hole) may be formed in an area avoiding the first flow path 6 in at least one of an upper portion (top portion) and a lower portion (bottom portion) of the movable element 2.

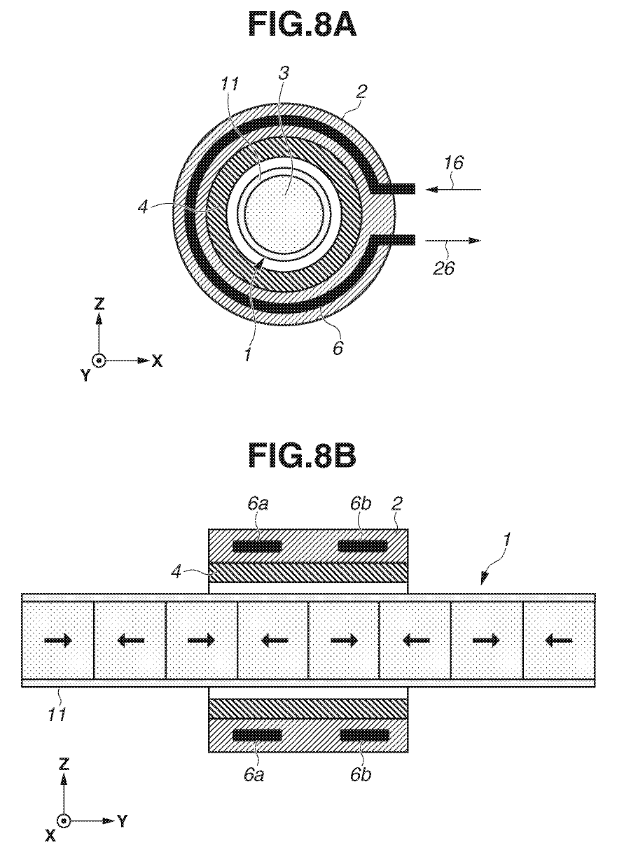

FIGS. 8A and 8B are diagrams each illustrating another example of the electromagnetic actuator according to the present embodiment. The electromagnetic actuator illustrated in FIGS. 8A and 8B is, for example, a shaft motor, and the stator 1 includes a pipe 11 and a plurality of magnets 3 that are disposed inside the pipe 11 and arranged in the Y-axis direction, which is a moving direction of the movable element 2. The pipe 11 contains, for example, a non-magnetic material. The cross-sectional shape of each of the stator 1 and the movable element 2 is a circular shape. The movable element 2 includes the coil 4 on an internal surface of the through-hole that extends through the movable element 2 in the Y-axis direction. Applying current to the coil 4 in the movable element 2 generates heat in the coil 4, but the fluid flowing through the first flow path 6 formed by a hole cools the entire movable element 2, so that an amount of heat transferred to the magnets 3 in the stator 1 is reduced and demagnetization of the magnets 3 is controlled. Controlling demagnetization means reducing the amount of demagnetization to zero or to an amount small enough not to affect performance.

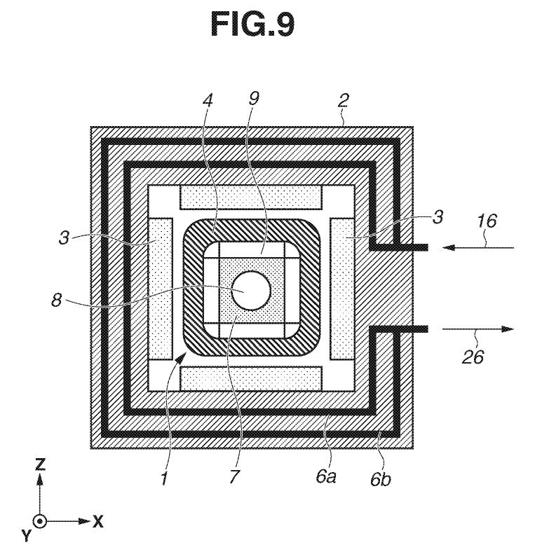

FIG. 9 is a diagram illustrating another example of the electromagnetic actuator according to the present embodiment and is a cross-sectional view illustrating the X-Z cross section of the electromagnetic actuator. In the example in FIG. 9, the first flow path 6 formed by a hole is configured in a double structure in the X-Z cross section, and a first flow path 6 formed by a first hole 6a and a second hole 6b are disposed. In this manner, the first flow path 6 may be configured in a double structure. In a case where the first flow path 6 is configured in a double structure, for example, the two flow paths may be provided so as to be located at the same position in the Y-axis direction.

In addition, such a double flow path may also be disposed at a plurality of positions different from each other in the Y-axis direction. Such a configuration can further reduce the temperature rise outside the movable element 2.

As described above, the fluid is caused to flow along the through-hole formed in the movable element 2 with use of the flow path(s) formed by a hole(s) provided in the movable element 2, as in the examples in FIGS. 4A to FIG. 9, so that demagnetization of the magnets 3 is controlled. It is sufficient that the magnets 3 are arranged in either the stator 1 or the movable element 2, and the coils 4 are arranged in the other of the stator 1 and the movable element 2, and whether the magnets 3 are arranged in the stator 1 or the movable element 2 is not specifically limited. The number of the magnets 3 to be arranged and the number of the coils 4 to be arranged are also not specifically limited. The cross-sectional shape of each of the stator 1 and the movable element 2 is not limited to rectangular shape or the circular shape in the X-Z cross section, and is not specifically limited. In the present embodiment, examples are illustrated in which the first flow path 6 is disposed in a shape in which a plurality of straight lines is connected in the X-Z cross section and in a shape including an arc portion. Alternatively, the first flow path 6 may be disposed in a wavy shape in the X-Z cross section, and the shape of the first flow path 6 is not specifically limited.

The diameter of the first flow path 6 (an inner diameter of the hole) is, for example, 10 mm, but may be 5 mm or less. The flow rate of the fluid flowing through the first flow path 6 is, for example, 4.5 L/min, and the flow velocity is, for example, 3 m/sec.

To enhance the cooling effect of the fluid flowing through the first flow path 6, the movable element 2 may contain a material having a high thermal conductivity such as aluminum, copper, silver, or a high thermal conductivity ceramic. Specifically, the movable element 2 may contain a material with a high thermal conductivity of 30 W/m∙K

or more. The movable element 2 may contain a material having a high thermal conductivity of 50 W/m∙K, 100 W/m∙K, or more. To enhance the cooling effect of the fluid flowing through the first flow path 6, the surface area of the first flow path 6 may be increased. In addition, the first flow path 6 in the movable element 2 may be located in the proximity of the magnet 3 or the coil 4 of the movable element 2. For example, as illustrated in FIG. 4A, a distance L in the X-Z cross section between one of the magnets 3 or the coil 4 and the first flow path 6 (a position at which the fluid flows) may be equal to or less than half of a thickness T of the movable element 2 in the X-Z cross section.

Providing the first flow path 6 can reduce an amount of the fluid, for cooling the magnets 3 or the coil(s) 4, flowing through the second flow path 8 on the stator 1 side. To cool the entire stator 1, which has a long length, for example, frequently used coils 4 and less frequently used coils 4 are uniformly cooled. In contrast, the fluid flowing through the first flow path 6 disposed in the movable element 2 cools the movable element 2, so that efficient cooling can be achieved.

In the present embodiment, the description has been provided using the reticle stage 140 as an example, but at least one of the features in the present embodiment may be applied to the substrate stage 170. Alternatively, at least one of the features in the present embodiment may be applied to a linear motor in the illumination optical system 120. The linear motor is used for, for example, driving of a masking blade in the illumination optical system 120. In the present embodiment, an example in which the substrate processing apparatus 100 is a projection exposure apparatus has been described, but the substrate processing apparatus 100 is not limited to the projection exposure apparatus. For example, the substrate processing apparatus 100 may be a drawing apparatus that performs drawing on a substrate using electron beams, ion beams, or the like to form a pattern on the substrate. The substrate processing apparatus 100 may be another lithography apparatus (substrate exposure apparatus), and may be, for example, an imprint apparatus that forms a pattern on the substrate by molding an imprint material on the substrate using a mold. Alternatively, the substrate processing apparatus 100 may be another apparatus that processes a substrate such as a semiconductor wafer or a glass plate. Example of the other apparatus include an ion implantation apparatus, a developing apparatus, an etching apparatus, a film forming apparatus, an annealing apparatus, a sputtering apparatus, and a vapor deposition apparatus. The substrate processing apparatus 100 may be a planarizing apparatus that uses a flat plate to planarize a composition on a substrate. In a case where the drawing apparatus, the imprint apparatus, and the other apparatus that processes the substrate, which have been described above, do not include a reticle stage, at least one of the features in the present embodiment may be applied to a substrate stage in each of these apparatuses.

The application of the present embodiment is not limited to substrate processing apparatuses, and the present embodiment can be applied to any actuator that includes a movable element and a stator. For example, the present embodiment can also be applied to an actuator that is used in fields such as machine tool manufacturing and railways.

### <Second Embodiment>

A stage according to a second embodiment is characterized in that, in addition to the features of the first embodiment, a third flow path 14 is arranged.

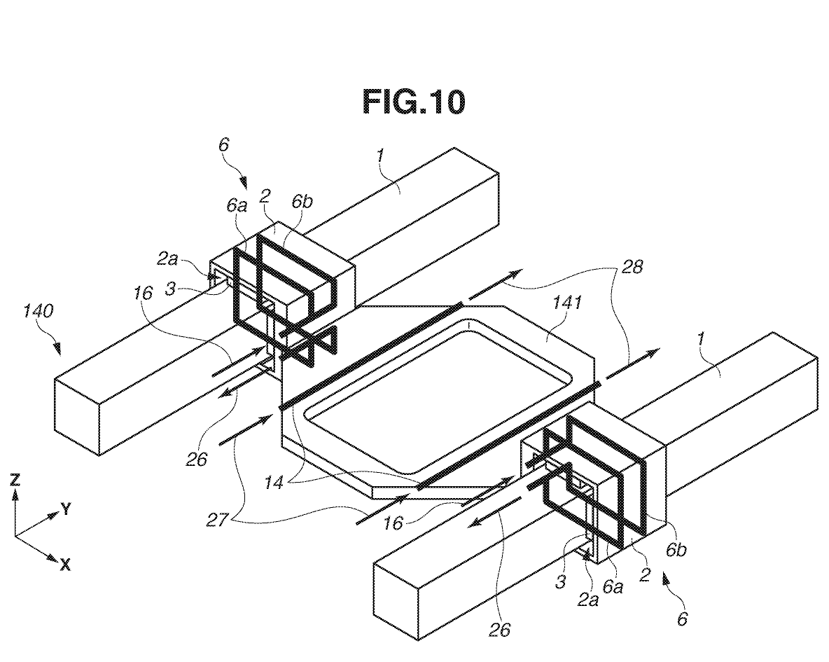

FIG. 10 illustrates an example of an arrangement of the third flow path 14 according to the present embodiment. The third flow path 14 according to the present embodiment is provided in the coupling portion 141. This makes it possible to reduce heat transfer from an actuator to objects supported by the coupling portion 141 (e.g., the reticle chuck 142 and the reticle 130 illustrated in FIG. 2).

The third flow path 14 is, for example, provided by arrangement of a flow path forming member (unit) such as a polyurethane tube or a metal pipe on the surface of the coupling portion 141 or inside the coupling portion 141. Alternatively, the third flow path 14 is provided by cutting the coupling portion 141 using a tool such as a drill. The hole formed by such cutting (the third flow path 14) serves as piping for allowing the fluid to flow, and serves as a flow path. As described above, the third flow path 14 includes the hole (the inside of the hole) through which the fluid flows or the hole (the inside of the hole) in a unit including a hole through which the fluid flows, such as a pipe.

In the example in FIG. 10, the fluid flows through the third flow path 14 from the -Y direction side as indicated by an arrow 27, and is discharged to the +Y direction side as indicated by arrow 28. The flow direction of the fluid is not limited to the example in FIG. 10, and the fluid is supplied from the +Y direction side into the third flow path 14 and discharged to the -Y direction side as indicated by arrow 28.

Each of the first flow path 6 and the third flow path 14 may have an independent temperature adjustment system. Differentiating the temperature of the fluid flowing through the first flow path 6 and the temperature of the fluid flowing through the third flow path 14 makes it possible to set the temperature of the first flow path 6 to an appropriate temperature value for the magnet 3. Additionally, the temperature of the third flow path 14 can be set to an appropriate temperature value for the objects supported by the coupling portion 141.

In the example in FIG. 10, the number of the third flow paths 14 is one on the +X direction side of the coupling portion 141 and one on the −X direction side of the coupling portion 141, without being so limited. For example, a single third flow path 14 may be provided only on either the +X direction side or the −X direction side.

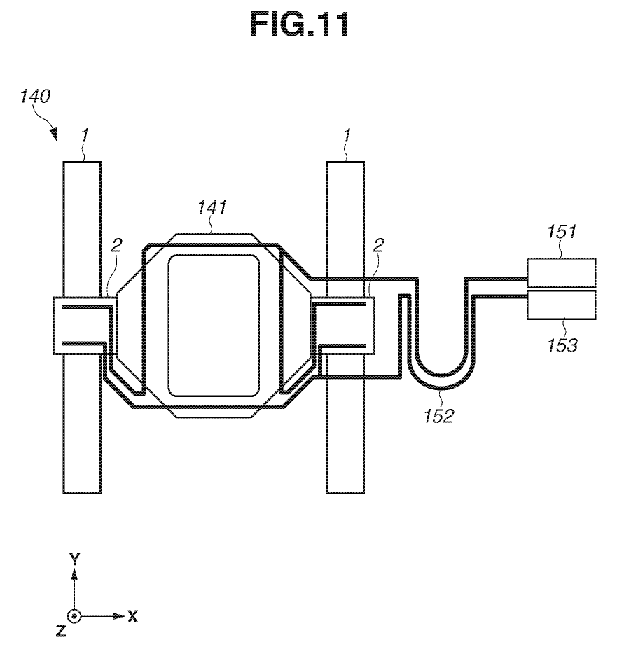

Here, the first flow path 6 and the third flow path 14 may be connected to each other. FIG. 11 illustrates an example in which the first flow paths 6 on the right and left sides and the third flow paths 14 on the right and left sides are connected to a supply unit 151 and a discharge unit 153 via a movable tube 152. The fluid is supplied from the supply unit 151, flows into the third flow path 14 via the movable tube 152 having flexibility, and flows from the third flow path 14 to the first flow path 6. The fluid that has flowed to the first flow path 6 flows to the discharge unit 153 via the movable tube 152. The movable tube 152 is deformable according to driving of the reticle stage 140. That is, in the example in FIG. 11, a plurality of first flow paths 6 (first flow path and second flow path) is connected to a third flow path that is shared for fluid supply or fluid collection.

The configuration is not limited to the example in FIG. 11, and the first flow path 6 and the third flow path 14 may be configured to receive the fluids from separate supply units and discharge the fluids to separate discharge units.

In the present embodiment, the description has been provided using the reticle stage 140 as an example, but at least one of the features in the present embodiment may be applied to the substrate stage 170. In the present embodiment, the description has been provided of an example in which the third flow path 14 is provided in mechanisms on respective sides of the coupling portion 141 with respect to the two electromagnetic actuators that are separated from each other in the X-axis direction, but the present embodiment can be applied only to the mechanism of a single electromagnetic actuator.

### <Third Embodiment>

The present embodiment relates to a method of manufacturing a product, which is characterized by using the electromagnetic actuator described above.

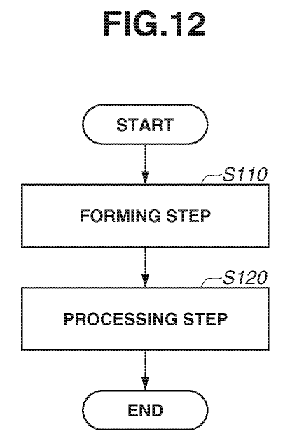

FIG. 12 is a flowchart of the method of manufacturing a product in the present embodiment. In step S110, a forming step is performed in which a pattern is formed on a substrate using an exposure apparatus. Subsequently, in step S120, a processing step is performed in which the substrate on which the pattern has been formed in the forming step is processed. The exposure apparatus includes the electromagnetic actuator described in the first embodiment or the second embodiment.

Examples of the product manufactured by the manufacturing method include a semiconductor integrated circuit (IC) element, a liquid crystal display element, a color filter, and a microelectromechanical system (MEMS).

In the forming step, the substrate (silicon wafer, glass plate, or the like) coated with a photosensitive material is exposed to light by the exposure apparatus (the lithography apparatus), thus forming the pattern on the substrate.

The processing step includes, for example, developing the substrate (photosensitive material) on which the pattern has been formed, etching and resist stripping of the developed substrate, dicing, bonding, and packaging.

The present disclosure is not limited to the above-mentioned embodiments, and can be changed and modified in various manners without departing from the spirit and range of the present disclosure. Thus, the claims are attached hereto to publicize the scope of the present disclosure.

According to the present disclosure, an electromagnetic actuator is provided for reducing demagnetization of a magnet by using a flow path in the movable element.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims priority to and the benefit of Japanese Patent Application No. 2024-199435, filed November 15, 2024, which is hereby incorporated by reference herein in its entirety.

What is claimed is:

1. An electromagnetic actuator comprising:
a stator extending in a first direction; and
an element configured to be movable along the first direction,
wherein one of the stator and the element includes a magnet and the other of the stator and the element includes a coil,
wherein the element has a through-hole extending in the first direction,
wherein the stator extends through the through-hole, and
wherein the element has, at a position along the through-hole, a hole configured for fluid to flow through.

2. The electromagnetic actuator according to claim 1,
wherein the element includes a first hole through which fluid flows along the through-hole at a first position in the first direction, and a second hole through which fluid flows along the through-hole at a second position in the first direction, the second position being different from the first position, and
wherein the first hole and the second hole each extend around the through-hole in a circumferential direction of the through-hole.

3. The electromagnetic actuator according to claim 1, wherein the hole is formed in a portion corresponding to a wall of the element, and
wherein one of a tube is disposed in the hole in the element, and the tube is disposed on an outer surface of the element.

4. The electromagnetic actuator according to claim 1, wherein the hole is formed in a circumference of the through-hole in a cross-section of the element, the cross-section being orthogonal to the first direction.

5. The electromagnetic actuator according to claim 1, wherein a distance between the fluid flows and the magnet or the coil disposed in the element is equal to or less than half of a cross-sectional thickness of the element, orthogonal to the first direction.

6. The electromagnetic actuator according to claim 1, wherein the hole is disposed inside a convex portion on an outer surface of the element.

7. The electromagnetic actuator according to claim 1, wherein the fluid flows through the stator to cool the magnet or the coil in the stator.

8. The electromagnetic actuator according to claim 1, further comprising:
another stator and another element; and
a member configured to move together with the element and the another element in the first direction,
wherein the stator and element are arranged on a first side of the member and the another stator and the another element are arranged on a second side of the member, with the first side and the second side being disposed on opposite sides of the member.

9. The electromagnetic actuator according to claim 1, wherein the fluid is configured to be subjected to temperature adjustment.

10. The electromagnetic actuator according to claim 1, further comprising a support member coupled to the element and configured to support an object,
wherein the support member has a hole through which fluid flows.

11. The electromagnetic actuator according to claim 10, wherein a temperature of the fluid flowing through the hole in the element and a temperature of the fluid flowing through the hole in the support member are different from each other.

12. The electromagnetic actuator according to claim 10, wherein the fluid flowing through the hole in the element and the fluid flowing through the support member are supplied from a supply unit.

13. The electromagnetic actuator according to claim 1, wherein at least one of a flow rate and a temperature of the fluid is adjusted based on a moving state of the element.

14. The electromagnetic actuator according to claim 1, wherein at least one of a flow rate, a flow velocity, and a temperature of the fluid is adjusted according to at least one of the temperature of the fluid, a temperature of the element, and a temperature of the magnet.

15. The electromagnetic actuator according to claim 1,
wherein the element includes a yoke, and
wherein the yoke has a hole for allowing the fluid to flow.

16. An electromagnetic actuator comprising:
a stator; and
an element configured to move along a direction in which the stator extends,
wherein one of the stator and the element includes a magnet and the other of the stator and the element includes a coil,
wherein the element has a first hole extending in the direction,
wherein at least a part of the stator is located in the first hole,
wherein the element has a second hole at a first position and a third hole at a second position, the first position and the second position being different from each other in the direction, and
wherein the second hole and the third hole each extend around the first hole in a circumferential direction of the first hole.

17. The electromagnetic actuator according to claim 16, wherein the first hole and the second hole are connected to a flow path that is shared for fluid supply or fluid collection.

18. The electromagnetic actuator according to claim 16, wherein the stator and the element are arranged as a first pair, the electromagnetic actuator further comprising:
another stator and another element arranged as a second pair;
and
a coupling member configured to couple the first pair, the second pair, and a driven object, to fixed the first pair and the second pair on respective sides of the driven object, with respect to a direction orthogonal to the direction,
wherein the coupling member includes at least one flow path forming member.

19. An exposure apparatus comprising:
the electromagnetic actuator according to claim 1, the electromagnetic actuator being configured to move a substrate or a reticle; and
a pattern forming unit configured to form a pattern on the substrate.

20. A method of manufacturing a product, the method comprising:
forming a pattern on the substrate using the exposure apparatus according to claim 19; and
processing the substrate on which the pattern has been formed in the forming.
